(19) United States
(12) Patent Application Publication
(10) Pub. No.: US 2011/0083065 A1
(43) Pub. Date: Apr. 7, 2011

(54) False Detection Reduction in Communication Systems

(75) Inventors: Amit Singh, Lund (SE); Göran Bergman, Lund (SE); Gustaf Claëson, Lund (SE)

(73) Assignee: Telefonaktiebolaget L M Ericsson (publ), Stockholm (SE)

(21) Appl. No.: 12/652,465

(22) Filed: Jan. 5, 2010

Related U.S. Application Data
(60) Provisional application No. 61/247,599, filed on Oct. 1, 2009.

(51) Int. Cl. H03M 13/09; G06F 11/10

(52) U.S. Cl. 714/807; 714/E11.032

(57) ABSTRACT

A decoding-reliability metric from a received-signal decoder is compared with a threshold to decrease significantly the probability of false detection in a receiver and thus increase communication reliability and performance. In a wideband code division multiple access communication system, for example, significant decrease of the probability of false grant-message detection and significant increases of enhanced uplink performance and reliability can be obtained.

### CROSS-REFERENCE TO RELATED APPLICATION

This application claims the benefit of the filing date of U.S. Provisional Patent Application No. 61/247,599 filed on Oct. 1, 2009, which is incorporated here by reference.

### TECHNICAL FIELD

This invention relates to electronic digital communication systems and more particularly to cellular radio telephone systems.

### BACKGROUND

Digital communication systems include time-division multiple access (TDMA) systems, such as cellular radio telephone systems that comply with the GSM telecommunication standard and its enhancements like GSM/EDGE, and code-division multiple access (CDMA) systems, such as cellular radio telephone systems that comply with the IS-95, cdma2000, and wideband CDMA (WCDMA) telecommunication standards. Long Term Evolution (LTE) can be seen as an evolution of the current WCDMA standard. Digital communication systems also include “blended” TDMA and CDMA systems, such as cellular radio telephone systems that comply with the universal mobile telecommunications system (UMTS) standard, which specifies a third generation (3G) mobile system being developed by the European Telecommunications Standards Institute (ETSI) within the International Telecommunication Union's (ITU's) IMT-2000 framework. The Third Generation Partnership Project (3GPP) promulgates the UMTS, LTE, WCDMA, and GSM standards, and specifications that standardize other kinds of cellular radio communication systems. This application focusses on WCDMA systems for simplicity, but it will be understood that the principles described in this application can be implemented in other digital communication systems.

Efficiency of uplink (i.e., the mobile-station-to-base-station, or reverse, direction) transmission and maximization of the available network capacity are achieved by carefully scheduling the uplink (UL) transmissions of the usually many mobile stations (MSs) in a base station's cell. The base station (BS) mainly providing service to a MS is usually called the MS's “serving” BS or cell. The serving BS informs its individual MSs of when they are allowed to transmit, and at which power level, so that the total power in the cell and the noise remain within the acceptable limits.

An MS's permission to transmit in the UL is transported from the serving BS to the MS by an absolute grant message sent by the BS in the downlink (i.e., the base-station-to-mobile-station, or forward, direction). Due to its importance, the absolute grant message is encoded and includes cyclic redundancy check (CRC) bits for error detection and correction. The CRC bits help ensure that an MS decodes the grant message correctly when a message is actually sent by a BS, but that may not be enough to stop an MS from falsely detecting a grant message when no message was sent. Through random chance, bits decoded by an MS can sometimes match valid CRC bits, with the result that the MS “detects” a false grant message. Such false grant messages are sometimes called “ghost grants”.

Because absolute grant messages indirectly control the UL power level, false detections detrimentally affect network capacity and MS throughputs. A false grant message sets a MS's transmit power to a level different from the level intended by a serving BS and can cause interference with other MSs. Therefore, there is a need for improved methods and apparatus of signal detection that reduce the number or probability of false detections.

### SUMMARY

In accordance with aspects of this invention, there is provided a method of decoding a received signal in a communication system. The method includes partially decoding the received signal, including generating a decoding-reliability metric value and cyclic redundancy check (CRC) information; checking the generated CRC information; comparing the decoding-reliability metric value with a threshold; if the generated CRC information checks and the decoding-reliability metric value passes the threshold, completing decoding the received signal; and otherwise, discarding the received signal.

Also in accordance with aspects of this invention, there is provided an apparatus in a receiver in a communication system. The apparatus includes a decoder configured to partially decode a signal received by the receiver and to generate a respective decoding-reliability metric value and CRC information; and an electronic processor configured to check the generated CRC information and to compare the decoding-reliability metric value with a threshold. If the generated CRC information checks and the decoding-reliability metric value passes the threshold, the received signal is completely decoded; otherwise, the received signal is discarded.

Also in accordance with aspects of this invention, there is provided a computer-readable medium having stored instructions that, when executed by a computer, cause the computer to perform a method of decoding a received signal in a communication system. The method includes partially decoding the received signal, including generating a decoding-reliability metric value and CRC information; checking the generated CRC information; comparing the decoding-reliability metric value with a threshold; if the generated CRC information checks and the decoding-reliability metric value passes the threshold, completing decoding the received signal; and otherwise, discarding the received signal.

### BRIEF DESCRIPTION OF THE DRAWINGS

The several features, objects, and advantages of this invention will be understood by reading this description in conjunction with the drawings, in which:

FIG. 1 depicts a cellular radio communication system;

FIG. 2 depicts a frame and subframe structure in a cellular radio communication system;

FIG. 3A depicts an encoding chain in a transmitter in a cellular radio communication system;

FIG. 3B depicts a decoding chain in a receiver in a cellular radio communication system;

FIG. 4 is a flow chart of a method of received signal processing in accordance with this invention;

FIG. 5 is portion of a receiver for a cellular radio communication system; and

FIG. 6 shows results of simulations of methods and receivers in accordance with this invention.

### DETAILED DESCRIPTION

This description focusses on a WCDMA communication system for efficient explanation, but the artisan will understand that the invention in general can be implemented in other communication systems.

This invention compares a metric from a received-signal decoder with a threshold to decrease significantly the probability of false detection in a receiver and thus increase UL reliability and performance. In a WCDMA system, for example, this invention enables significant decrease of the probability of false grant-message detection and significant increases of Enhanced Uplink performance and reliability.

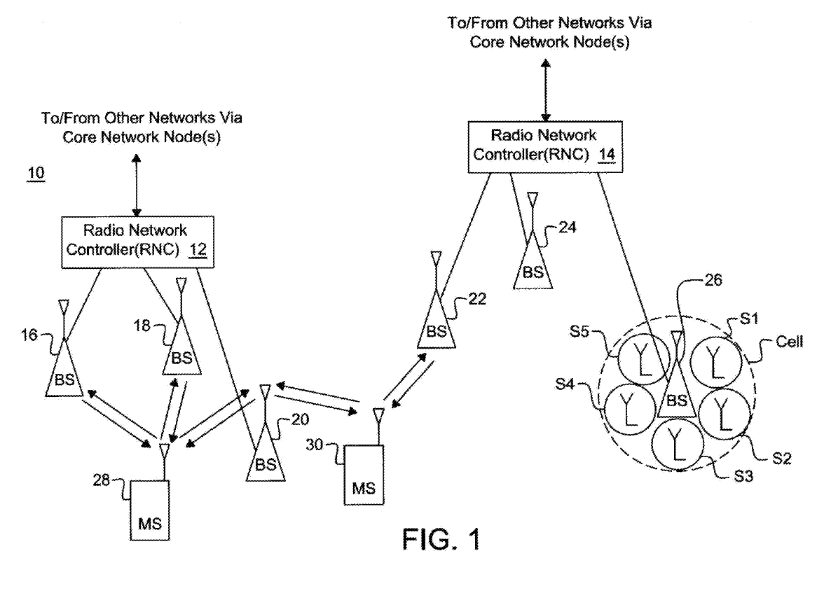

FIG. 1 depicts a cellular radio communication system 10, which may be, for example, a WCDMA radiotelephone system. Radio network controllers (RNCs) 12, 14 control various radio network functions, including for example radio access bearer setup, diversity handover, etc. More generally, each RNC directs calls to and from MSs, or user equipments (UEs), through the appropriate BS(s), which communicate with each MS through downlink (DL) and UL channels. RNC 12 is shown coupled to BSs 16, 18, 20, and RNC 14 is shown coupled to BSs 22, 24, 26. Each BS, or Node B, serves a geographical area that can be divided into one or more cell(s). BS 26 is shown as having five antenna sectors S1-S5, which can be said to make up the cell of the BS 26. The BSs are coupled to their corresponding RNCs by dedicated telephone lines, optical fiber links, microwave links, etc. Both RNCs 12, 14 are connected with external networks such as the public switched telephone network (PSTN), the Internet, etc. through one or more core network nodes, such as a mobile switching center (not shown) and/or a packet radio service node (not shown).

It should be understood that the arrangement of functionalities depicted in FIG. 1 can be modified. For example, the functionality of the RNCs 12, 14 can be moved to the Node Bs 22, 24, 26, and other functionalities can be moved to other nodes in the network. It will also be understood that a base station can use multiple transmit antennas to transmit information into a cell/sector/area, and those different transmit antennas can send respective, different signals.

WCDMA is based on direct-sequence spread-spectrum techniques, with pseudo-noise scrambling codes and orthogonal channelization codes separating BSs and physical channels (MSs), respectively, in the DL. Orthogonal variable spreading factor (OVSF) channelization codes are used in order to maintain link orthogonality while accommodating different user data rates.

Characteristics of physical and transport channels (Layer 1) in the frequency-division-duplex (FDD) mode of a WCDMA cellular radio communication system are defined in 3GPP TS 25.211 V8.4.0, Physical Channels and Mapping of Transport Channels onto Physical Channels (FDD) (Release 8) (March 2009), among other specifications. In general, transport channels are services offered by Layer 1 to higher layers and are defined by how data is transferred over the air interface between a BS and a MS. Dedicated channels use inherent addressing of MSs, and each of successive radio frames consists of fifteen time slots, with the length of a slot corresponding to 2560 chips, or 2/3 millisecond (ms). Each frame is also organized into successive subframes, each consisting of three slots, with the length of a subframe corresponding to 7680 chips, or 2 ms. A WCDMA communication system is described here, but it will be appreciated that other systems have equivalent features.

Another evolution of WCDMA is Enhanced Uplink (EUL), or High-Speed Uplink Packet Access (HSUPA), that enables high-rate packet data to be sent in the reverse direction. According to Section 5.3.3.14 of 3GPP TS 25.211, the enhanced dedicated channel (E-DCH) is a downlink physical channel that includes an E-DCH absolute grant channel (E-AGCH), which is a transport channel having a rate of 30 kilobits per second (kbps) and a spreading factor of 256 that carries uplink E-DCH absolute grant messages. These messages and channels are also described, for example, in Section 11.8 of 3GPP TS 25.321 V8.5.0, Medium Access Control (MAC) Protocol Specification (Release 8) (March 2009).

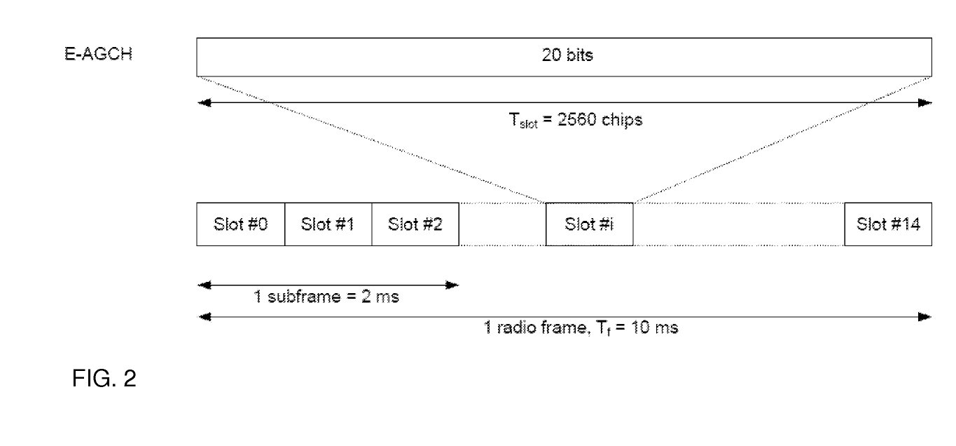

FIG. 2 depicts the above-described frame and subframe structure of the E-AGCH. An UL absolute grant message comprises 60 bits that are packaged in serving grant (SG) messages carried by the E-AGCH. According to Section 7.12 of 3GPP TS 25.211, the E-AGCH repeats five times in successive 2-ms-long subframes for 10-ms transmission time intervals (TTIs). It will be appreciated that the methods and apparatus described in this application can be used with other message formats in other types of communication system.

As described above, grant messages, as well as other information, are encoded or decoded for transport services over the air interface between a BS and an MS. In general, the channel coding scheme combines error detection and correction, rate matching, interleaving, and transport-channel mapping onto or from physical channels.

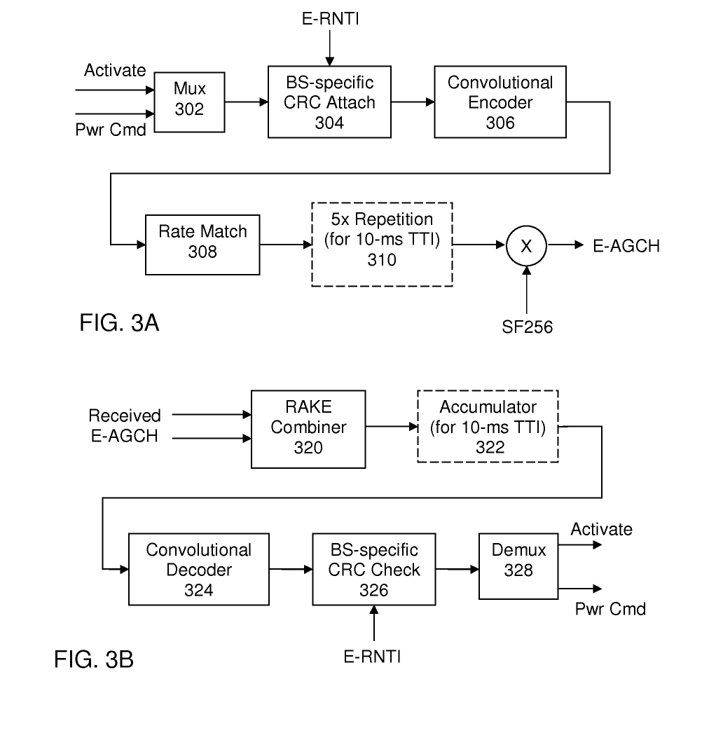

FIG. 3A depicts an encoding chain in a BS for the E-AGCH according to Section 4.10 of 3GPP TS 25.212 V8.5.0, Multiplexing and Channel Coding (FDD) (Release 8) (March 2009). A 1-bit activate flag and a 5-bit transmit power command are multiplexed together by a suitable multiplexer 302, and a 16-bit BS-specific CRC is attached to the multiplexed bits. The BS-specific CRC information is generated based on an E-DCH radio network identifier (E-RNTI). The combined bit sequence is encoded by a rate—1/3 convolutional encoder 306, and the resulting sequence is punctured by a suitable rate-matcher 308, thereby obtaining a rate-matched, 60-bit output sequence. If the TTI in use is 10 ms, the encoding chain includes a repeater 310 that generates five successive repetitions of the output sequence. The resulting output sequence is mapped to the physical channel by spreading with a SF=256 spreading sequence as the E-AGCH in a WCDMA system.

As depicted in FIG. 3B, an MS typically monitors the E-AGCH for grant messages with a decoding chain that effectively reverses the encoding process depicted in FIG. 3A. Received echoes of BS-transmitted E-AGCH signals are despread and combined by a RAKE combiner 320. If the TTI in use is 10 ms, the decoding chain includes an accumulator 422 that combines five successive repetitions of the received combined sequence. The received sequence is decoded by a suitable rate—1/3 convolutional decoder 324, such as a Viterbi decoder, that produces a local version of the 60-bit absolute grant sequence for each TTI. A CRC processor 326 checks the CRC information to determine if each sequence is properly decoded based on the BS-specific E-RNTI, and if so, the decoded sequence is provided to a demultiplexer 328, which separates the transmitted activate flag and the transmit power command. In case of a CRC match, the MS applies the received message as an SG command.

As WCDMA and other communication systems are currently specified, it is required that the E-AGCH be decoded for every TTI when the EUL functionality is turned on, even though the E-AGCH message is transmitted only when there is a change in the absolute grant. As noted above, the 16-bit CRC information is not enough to stop false AGCH message detection when no message is transmitted, and so sometimes the decoded bits match a valid CRC and a ghost grant is “detected”. It is currently believed that other error-detecting code information, such as a checksum that includes RNTI information, is equivalent to, although possibly less efficient and less widely used than the CRC information described above. The artisan should understand that CRC information as used in this application also refers to such equivalent information.

The probability of a false detection can be calculated as follows. The total number of valid AGCH messages N_{Valid} is 2⁶, for a 6-bit message, and the total number of combinations N_{Total} of 6-bit AGCH messages and 16-bit CRCs is 2²². The probability of false detection P_{fd} is given by:

$${P}_{fd} = \frac{{N}_{Valid}}{{N}_{Total}} = \frac{{2}^{6}}{{2}^{22}} = \frac{1}{65536}$$

which is to say that on average an MS will falsely detect an AGCH message once in every 65536 TTIs. That corresponds to a false detection about once every 131 seconds (on average) for a 2-ms TTI and about once every 655 seconds (on average) for a 10-ms TTI. This problem has been observed both in actual communication systems and in a computer simulation, which is described in more detail below.

The inventors have recognized that a decision-reliability metric generated by a decoder can be used with a suitable threshold to distinguish between false and correct decoding decisions and thereby decrease the probability of false detection. As a particular example, the so-called “s metric” that is generated by and output from a convolutional decoder represents the reliability of the decoding decision. Although it is not strictly necessary, it is common for a convolutional decoder to generate the s metric, which is discussed in Appendix 1.2 of 3GPP TS 25.212, among other places. The artisan will understand that any decoder, convolutional or otherwise, that generates a decision-reliability metric that is equivalent to the s metric can be used. For example, decoders for Turbo codes and low-density parity-check (LDPC) codes can generate suitable decision-reliability metrics. LDPC decoders are described in, for example, L. Yanping et al., “New Implementation for the Scalable LDPC-Decoders”, Proc. 59th Vehicular Technology Conference, vol. 1, pp. 343-346 (May 17-19, 2004).

The decoder's decision-reliability metric is used in combination with a tunable decision threshold to distinguish between false and correct decoding decisions. Let M_{S} represent a decoder's decision-reliability metric and let T^{S}_{AGCH} represent the decision threshold. If M_{S}<T^{S}_{AGCH}, the receiver discards the received message without checking its CRC information or further processing (leaving the MS's EUL transmit power unaffected, although the transmit power might be affected by other messages, such as relative grant messages carried by a Relative Grant Channel). If M_{S}≧T^{S}_{AGCH}, the received message is checked for CRC information, and if the CRC matches, then the MS acts on the received message, e.g., by changing its EUL transmit power accordingly. As an alternative, an MS can check the CRC information in a received message before testing its decoder's decision-reliability metric. If the CRC matches, the metric is compared to the decision threshold, and the message is discarded if the metric does not pass the threshold or is acted on if the metric passes the threshold.

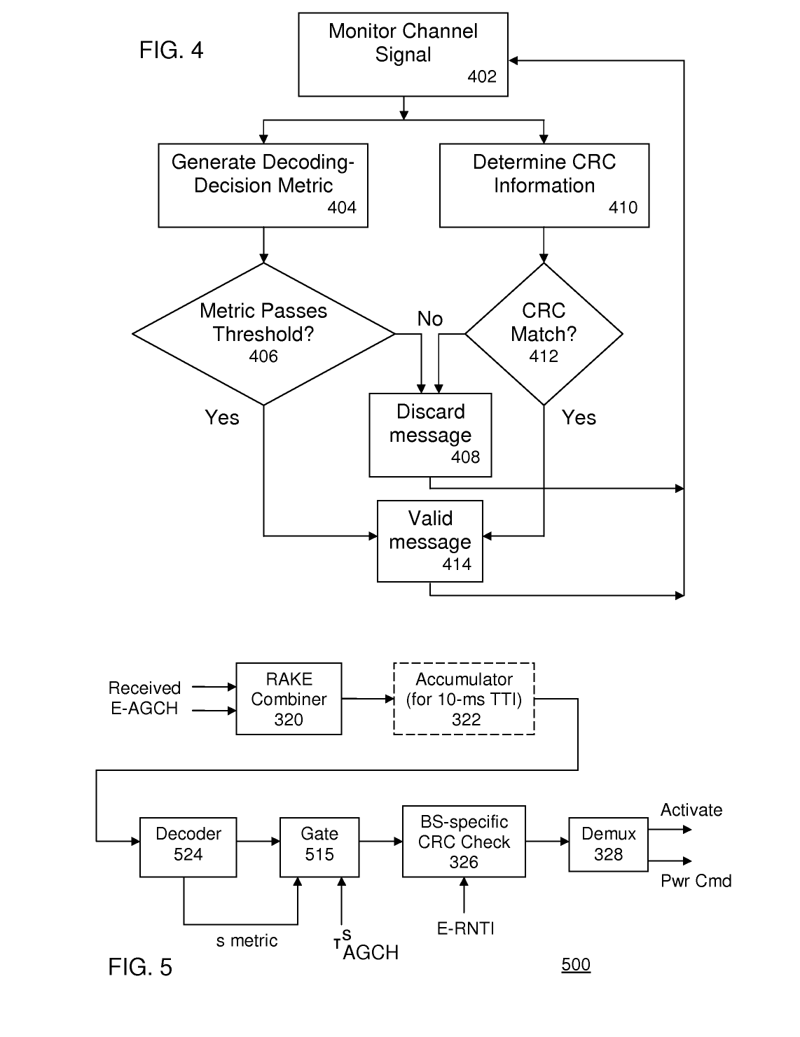

FIG. 4 is a flow chart of a method of decoding a received signal as described above. In step 402, the receiver monitors a channel for messages, and in step 404, a received signal is at least partially decoded so as to generate a decoding-reliability metric. In step 406, the decoding-reliability metric is compared with a decision threshold. If the metric does not pass the threshold (No in step 406), the “message” is discarded in step 408 and the flow returns to step 402. In step 410, CRC or equivalent information in the received signal is determined, and in step 412, the CRC information is checked. If the determined CRC does not match (No in step 412), the “message” is discarded in step 408 and the flow returns to step 402. If the metric passes the threshold (Yes in step 406) and the CRC matches (Yes in step 412), the message is deemed valid in step 414, and the flow returns to step 402. The fully decoded valid message can then be implemented by the receiver. As described above, It will be understood that the steps 404, 406 can be performed before the steps 410, 412, or after those steps, or even at the same time as those steps.

FIG. 5 is a block diagram of a portion of a receiver 500 that is suitable for implementing the methods depicted by FIG. 4. Components depicted in FIG. 5 that have substantially the same functionality as components depicted in FIG. 3B are identified by the reference numerals used in FIG. 3B. The receiver 500, such as an MS in a WCDMA or other communication system, includes a RAKE combiner 320 that despreads and combines one or more received versions or echoes of a radio channel signal, such as an E-AGCH signal. RAKE combining is well known in the art, and is described in, for example, U.S. Pat. No. 5,305,349 to Dent for “Quantized Coherent Rake Receiver”; No. 6,363,104 to G. Bottomley for “Method and Apparatus for Interference Cancellation in a Rake Receiver”; No. 6,801,565 to G. Bottomley et al. for “Multi-Stage Rake Combining Methods and Apparatus”; and No. 6,922,434 to Wang et al. for “Apparatus and Methods for Finger Delay Selection in Rake Receivers”. To handle the E-AGCH in which the TTI in use is 10 ms, the receiver 500 can include an accumulator 322 that combines five successive repetitions of the received combined sequence.

The received sequence is at least partially decoded by a suitable decoder 524, such as a convolutional decoder, that produces a local version of the 60-bit absolute grant sequence for each TTI, a local version of the transmitted CRC or equivalent information, and a decoding-reliability metric, such as the s metric. As depicted in FIG. 5, the decoding-reliability metric and a tunable threshold value control the operation of a gate 515 such that the gate either passes or discards the partially decoded received sequence generated by the decoder 524. As described above, the gate 515 can be implemented by a comparator that compares the decoding-reliability metric with the threshold. A partially decoded received sequence that is passed by the gate 515 is provided to a CRC processor 326 that checks the CRC bits to determine if the sequence is properly decoded based on the BS-specific E-RNTI, and if so, the decoded sequence is provided to a demultiplexer 328, which separates the transmitted activate flag and the transmit power command. In case of a CRC match, the receiver applies the received message, e.g., as an SG command.

It will be appreciated that the order of the CRC processor 326 and the gate 515 shown in FIG. 5 can be reversed such that the CRC information is checked before the metric and threshold are compared. Moreover, the CRC processor 326 and the gate 515 together can be considered an electronic signal processor that further decodes a partially decoded signal generated by the decoder 524 and that implements the steps 404, 406 before the steps 410, 412, or after those steps, or even at the same time as those steps. It will also be appreciated that many of the devices in the receiver 500 can be implemented by one or more suitably programmed electronic signal processors.

The threshold T^{S}_{AGCH} should be tuned so as to achieve an optimum balance between missed detections (false negatives) and false detections (false positives). If the threshold is set too low, good missed-detection performance but poor false-detection performance are obtained. On the other hand, if the threshold is set too high, poor missed-detection performance and good false-detection performance are obtained. Thus, a tradeoff is needed between the two. In a WCDMA system, the threshold should be separately tuned for 2-ms TTIs and 10-ms TTIs.

Computer simulations of the methods and apparatus described above were run for the 2-ms TTI case, which is currently believed to be the case that is most susceptible to false detections. In the simulations, the energy level of the received E-AGCH signal was chosen at Ec/Ior=−11 dB, with Ior/Ioc=0 dB, where Ec is the energy per chip and Ior and Ioc are respectively the interference power spectral density per channel bandwidth (e.g., 3.84 MHz) and the interference power spectral density per chip. Three simulations were carried out, each comprising 100 000 frames to determine the false-detection rate and 10 000 frames to determine the missed-detection rate. Since the probability of a false detection is low and would require a very large number of frames to estimate accurately, it was decided to record the s metric each time a false detection was observed.

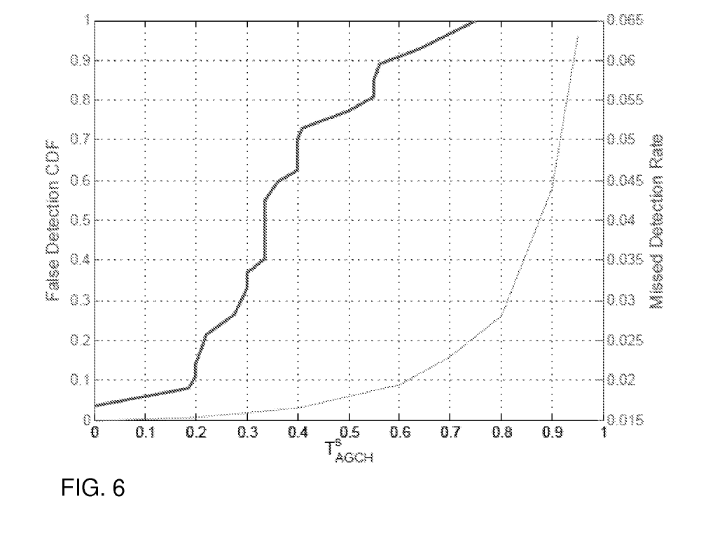

FIG. 6 shows the results of the simulations as a plot of the False Detection (false alarm) cumulative distribution function (CDF) (left-most curve) and the Missed Detection rate (right-most curve) against the s metric threshold T^{S}_{AGCH}. The scale for the False Detection CDF is on the left-hand side, and the scale for the Missed Detection rate is on the right-hand side. From FIG. 6, a suitable value of the s metric threshold T^{S}_{AGCH} can be selected.

It can be observed that an s metric threshold value of T^{S}_{AGCH}=0.6 prevents more than 90% of false detections at the same time that the missed-detection rate increases only slightly from its minimum value of 0.015 to a value of 0.019. A threshold value of T^{S}_{AGCH}=0.7 prevents 97% of false detections but the increase in the missed-detection rate is larger, from 0.015 to 0.024. A suitable value of the threshold, such as 0.6 or 0.7, can thus be selected by trading off the number of false detections and the missed-detection rate.

The artisan will understand that this description is given for a context of E-AGCH decoding, but it will be understood that the signal detection process described above can also be used in other situations where the relevant message set consists of a limited number of valid messages. For example, the process described above can be used for transport format combination indicator (TFCI) decoding in WCDMA communication systems, and other situations will be apparent to the artisan. It is particularly applicable to reception scenarios where the decoding performance (missed-detection and false-alarm probabilities) is constrained and messages contain a CRC or other validation mechanism, such as a checksum. Of course, the artisan will understand that a suitable decoding reliability metric similar to an s metric would be generated in the process of decoding such other messages and channels. As discussed above, Turbo decoders and LDPC decoders, among others, can generate suitable reliability metrics.

Those of ordinary skill in this art will understand that the above-described threshold values are examples and that other values could be used. It will also be appreciated that procedures described above are carried out repetitively as necessary, for example, to respond to the time-varying nature of communication signals exchanged by transmitters and receivers. To facilitate understanding, many aspects of this invention are described in terms of sequences of actions that can be performed by, for example, elements of a programmable computer system. It will be recognized that various actions could be performed by specialized circuits (e.g., discrete logic gates interconnected to perform a specialized function or application-specific integrated circuits), by program instructions executed by one or more processors, or by a combination of both. Wireless transceivers implementing embodiments of this invention can be included in, for example, mobile telephones, pagers, headsets, laptop computers and other mobile terminals, base stations, and the like.

Moreover, this invention can additionally be considered to be embodied entirely within any form of computer-readable storage medium having stored therein an appropriate set of instructions for use by or in connection with an instruction-execution system, apparatus, or device, such as a computer-based system, processor-containing system, or other system that can fetch instructions from a medium and execute the instructions. As used here, a “computer-readable medium” can be any means that can contain, store, or transport the program for use by or in connection with the instruction-execution system, apparatus, or device. The computer-readable medium can be, for example but not limited to, an electronic, magnetic, optical, electromagnetic, infrared, or semiconductor system, apparatus, or device. More specific examples (a non-exhaustive list) of the computer-readable medium include an electrical connection having one or more wires, a portable computer diskette, a random-access memory (RAM), a read-only memory (ROM), an erasable programmable read-only memory (EPROM or Flash memory), and an optical fiber.

Thus, the invention may be embodied in many different forms, not all of which are described above, and all such forms are contemplated to be within the scope of the invention. For each of the various aspects of the invention, any such form may be referred to as “logic configured to” perform a described action, or alternatively as “logic that” performs a described action.

It is emphasized that the terms “comprises” and “comprising”, when used in this application, specify the presence of stated features, integers, steps, or components and do not preclude the presence or addition of one or more other features, integers, steps, components, or groups thereof.

The particular embodiments described above are merely illustrative and should not be considered restrictive in any way. The scope of the invention is determined by the following claims, and all variations and equivalents that fall within the range of the claims are intended to be embraced therein.

What is claimed is:

1. A method of decoding a received signal in a communication system, comprising:
partially decoding the received signal, including generating a decoding-reliability metric value and cyclic redundancy check (CRC) information;
checking the generated CRC information;
comparing the decoding-reliability metric value with a threshold;
if the generated CRC information checks and the decoding-reliability metric value passes the threshold, completing decoding the received signal; and
otherwise, discarding the received signal.

2. The method of claim 1, wherein checking the generated CRC information is performed before comparing the decoding-reliability metric value with the threshold, and comparing is not performed if the generated CRC information does not check.

3. The method of claim 1, wherein comparing the decoding-reliability metric with the threshold is performed before checking the generated CRC information, and checking is not performed if the decoding-reliability metric value does not pass the threshold.

4. The method of claim 1, wherein partially decoding comprises convolutionally decoding, and the decoding-reliability metric value is an s metric value.

5. The method of claim 1, wherein the received signal is an absolute grant channel signal.

6. An apparatus in a receiver in a communication system, comprising:
a decoder configured to partially decode a signal received by the receiver and to generate a respective decoding-reliability metric value and cyclic redundancy check (CRC) information; and
an electronic processor configured to check the generated CRC information and to compare the decoding-reliability metric value with a threshold;
wherein if the generated CRC information checks and the decoding-reliability metric value passes the threshold, the received signal is completely decoded, and otherwise, the received signal is discarded.

7. The apparatus of claim 6, wherein the electronic processor is configured to check the generated CRC information before comparing the decoding-reliability metric value with the threshold, and not to compare the decoding-reliability metric value with the threshold if the generated CRC information does not check.

8. The apparatus of claim 6, wherein the electronic processor is configured to compare the decoding-reliability metric value with the threshold before checking the generated CRC information, and not to check the generated CRC information if the decoding-reliability metric value does not pass the threshold.

9. The apparatus of claim 6, wherein the decoder is a convolutional decoder, and the decoding-reliability metric value is an s metric value.

10. The apparatus of claim 6, wherein the received signal is an absolute grant channel signal.

11. A computer-readable medium having stored instructions that, when executed by a computer, cause the computer to perform a method of decoding a received signal in a communication system, wherein the method comprises:
partially decoding the received signal, including generating a decoding-reliability metric value and cyclic redundancy check (CRC) information;
checking the generated CRC information;
comparing the decoding-reliability metric value with a threshold;
if the generated CRC information checks and the decoding-reliability metric value passes the threshold, completing decoding the received signal; and
otherwise, discarding the received signal.

12. The medium of claim 11, wherein checking the generated CRC information is performed before comparing the decoding-reliability metric value with the threshold, and comparing is not performed if the generated CRC information does not check.

13. The medium of claim 11, wherein comparing the decoding-reliability metric with the threshold is performed before checking the generated CRC information, and checking is not performed if the decoding-reliability metric value does not pass the threshold.

14. The medium of claim 11, wherein partially decoding comprises convolutionally decoding, and the decoding-reliability metric value is an s metric value.

15. The medium of claim 11, wherein the received signal is an absolute grant channel signal.
